(19) United States
(12) Patent Application Publication
(10) Pub. No.: US 2008/0044775 A1
(43) Pub. Date: Feb. 21, 2008

(54) Method for Aligning or Assembling Nano-Structure on Solid Surface

(76) Inventors: Seung-Hun Hong, Seoul (KR); Min-Baek Lee, Seoul (KR); Ji-Woon Im, Seoul (KR)

Correspondence Address: VENABLE LLP, P.O. BOX 34385, WASHINGTON, DC, 20043-9998, US

(21) Appl. No.: 11/667,600

(22) PCT Filed: Nov. 11, 2005
(86) PCT No.: PCT/KR05/03831

§ 371 Date: May 11, 2007

(30) Foreign Application Priority Data
Nov. 12, 2004 (KR) 10-2004-0092596
Nov. 9, 2005 (KR) 10-2005-0106975

(51) Int. Cl. G03F 7/00

(52) U.S. Cl. 430/323; 430/322

(57) ABSTRACT

The present invention relates to a method for selectively assembling and aligning nano-structures on a solid surface; and, more particularly, to a method for directly adsorbing the nano-structures on the solid surface with sliding the nano-structure from a slippery molecular layer to the solid surface after the solid surface is patterned into the slippery molecular layer. And the present invention can prevent the contamination of the nano-structure and the solid surface since the nano-structure is in direct contact with the solid surface. Further, the multi nano-structure manufactured in accordance with the present invention can be utilized as a sensor and is capable of adsorbing and cultivating bio-structures such as DNAs, proteins, cells or the like into desired shapes.

### TECHNICAL FIELD

The present invention relates to a method for selectively positioning and aligning nano-structures on a solid surface; and, more particularly, to a method for directly adsorbing and aligning the nano-structures on molecular patterned solid surfaces through sliding motion of the nano-structures over a slippery molecular layer patterned on the solid surface.

### BACKGROUND ART

Recently, many prototypes of devices using nano-tubes, nano-wires or the like have been developed by the development of the nano-technology. In a certain application field, the device using nano-wires shows excellent property in comparison with a conventional semiconductor device. For example, there is a carbon nano-tube interconnector to withstand an ultra high current density, a high speed flexible circuit made of silicon nano-wires, a high sensitive detector using nano-wires or the like.

For the case of devices using nano-structures, since most types of nano-structures are synthesized into a solution or powder form, in order to manufacture the circuit, it is required to process for aligning the nano-wire to specific positions on the solid surface with a desired directionality. But, it is a very difficult task in considering that the diameter of the nano-wire is in the order of nanometers and the length of the nano-wire is several micrometers. Practically, due to such reason, although many devices have been developed using nano-wires, the commercialization of these devices is not being realized.

A flow cell and linker molecule methods are well known as technology to adsorb and align conventional nano-wires.

The flow cell method according to C. M. Lieber of Harvard University is shown in FIG. 2 (referring to U.S. patent application serial number US2003/00899). For the case of the flow cell method, after the nano-wire is adsorbed on the specific position of the solid surface, the nano-wire is guided to be aligned along the direction of a liquid flow by making the liquid control the direction of the nano-wire. In this case, although a large amount of nano-wires are aligned on a large scale area along the same direction, it is very difficult to arbitrarily adjust the direction of the nano-wire in the local area.

On the other hand, the method (referring to Nature 425, 36 (2003)) for aligning the carbon nano-tube on the solid surface using a linker molecular layer is schematically shown in FIG. 3.

The method using the linker molecular layer is a method that two types of different molecular layers are patterned on the solid surface and the nano-wires are adsorbed on specific positions using the difference of adsorption property for the nano-wires of each molecular layer surface.

In this case, during the adsorption of the nano-wires on the molecular layer, the nano-wires are aligned to the direction of the molecular layer pattern. As one example, for the carbon nano-tube, while the carbon nano-tube is selectively adsorbed on the hydrophilic molecular layer, the adsorbed carbon nano-tubes are aligned along the molecular pattern. In this process, since the nano-tubes are aligned along the direction of the local molecular pattern without utilizing the flow cell method for the nano-tube alignment, it is possible to locally adjust the direction and the position of the nano-tubes.

However, in the case of this method, since there is always linker molecule between nanotubes and solid surfaces, it has a problem to contaminate the nano-wire or the sample.

### DISCLOSURE

### Technical Problem

It is, therefore, an objective of the present invention to provide a method for selectively assembling and aligning nano-structures on a solid surface in a desired shape utilizing sliding motion of the nano-structure on a slippery molecular layer.

It is another objective of the present invention to provide a method for selectively assembling and aligning a nano-structure on a solid surface capable of reducing the degree of contamination of the solid surface and the nano-structure by directly adsorbing the nano-structure on the solid surface not using linker molecules.

### Technical Solution

In accordance with an aspect of the present invention, there is provided a method for selectively positioning or aligning nano-structures on a solid surface using a slippery molecular layer as a method for patterning the nano-structure on the solid surface, the method comprising the steps of: patterning the slippery molecular layer on the solid surface into an isotropic or an anisotropic shape, wherein the interface energy for the nano-structure to be adsorbed on the slippery molecular layer is higher than that on the solid surface; immerging the solid, of which the surface is patterned by the slippery molecular layer, into a nano-structure solution containing the nano-structures; directly adsorbing the nano-structures on the solid surface regions without the slippery molecular layer which enables the adsorbing and sliding of the nano-structures; and removing the nano-structure adsorbed on the slippery molecular layer by cleaning the solid surface with a washing solution.

In accordance with another aspect of the present invention, there is provided a method for selectively positioning or aligning different kinds of nano-structures on the same solid surface using a slippery molecular layer further comprising the steps of: further patterning the same of the previously patterned slippery molecular layer or a different slippery molecular layer on the solid surface at which the nano-structure is selectively positioned and aligned; further patterning a nano-structure adsorption layer with a lower interface energy for the additional nano-structure to be further adsorbed on the portion except the slippery molecular layer; and adsorbing the additional nano-structure on the nano-structure adsorbing layer by immerging the nano-structure assembled solid into the solution containing another kind of nano-structure.

In accordance with another aspect of the present invention, there is provided a method for selectively positioning or aligning a nano-structure on a solid surface using a slippery molecular layer, wherein if a signal is transmitted to the solid surface at which the nano-structure is selectively positioned or aligned, the transmitted signal is amplified and the amplified signal is detected.

In accordance with another aspect of the present invention, there is provided a method for manufacturing a bio-structure aligned or cultivated on a nano-structure selectively aligned using a slippery molecular layer, the method comprising the steps of: aligning the nano-structure into a predetermined shape on a solid surface and aligning and cultivating the bio-structure by adsorbing the bio-structure on the nano-structure with the predetermined shape.

### ADVANTAGEOUS EFFECTS

In accordance with the present invention, the present invention can selectively position and align a nano-structure on a solid surface. And also, the present invention can prevent the contamination of the nano-structure and the solid surface since the nano-structure is in direct contact with the solid surface.

And, a multi nano-structure manufactured in accordance with the present invention can be utilized as a sensor. Further, the present invention can adsorb and cultivate a bio-structure such as DNA, protein, cell or the like into a desired shape.

### DESCRIPTION OF DRAWINGS

The above and other objectives and features of the present invention will become apparent from the following description of the preferred embodiments given in conjunction with the accompanying drawings, in which:

FIG. 1 is a schematic diagram showing an example of recently developed prototype devices using nano-wires and a nanomanufacturing problem that is an obstacle in commercializing the prototype devices;

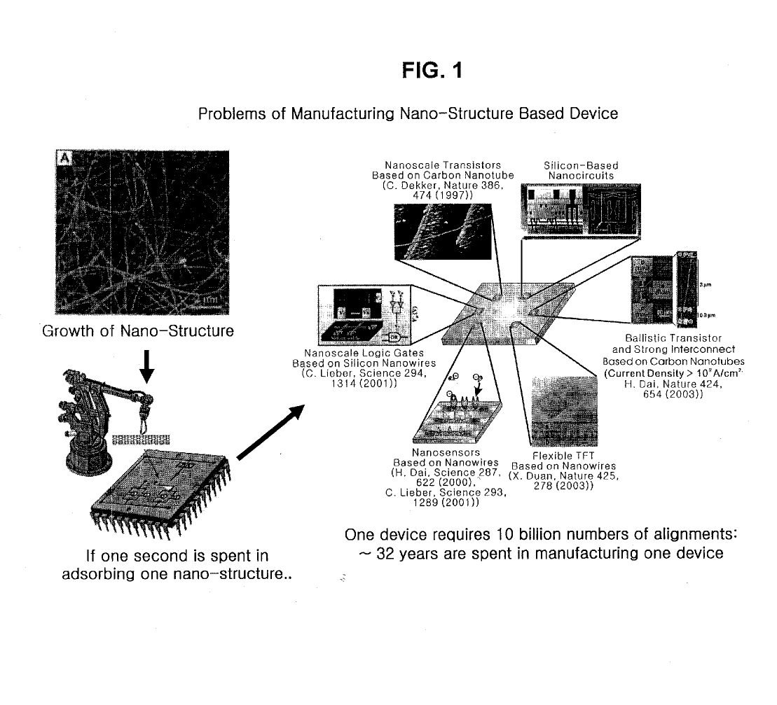

FIG. 2 is a schematic diagram illustrating the previous method to align a nano-wire on a solid surface using a flow cell;

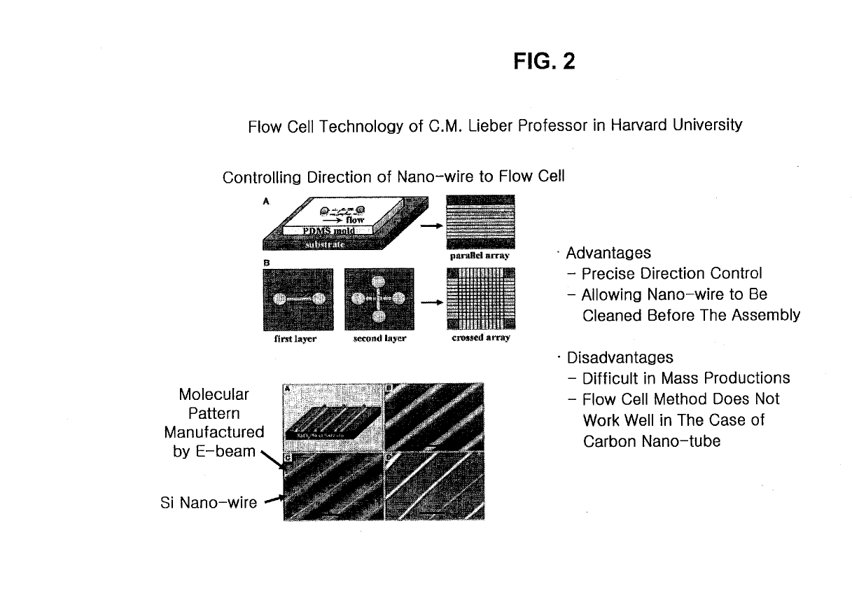

FIG. 3 is a schematic diagram showing the previous method to align a carbon nano-tube on a solid surface using a linker molecular layer;

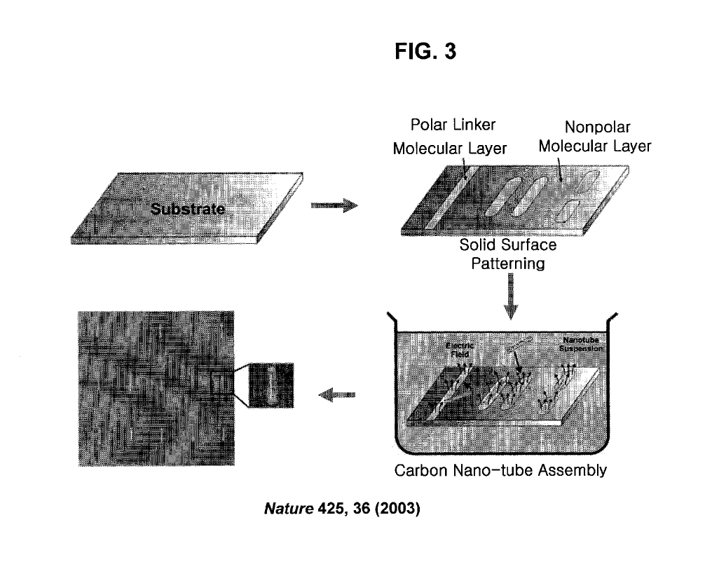

FIG. 4 is a schematic diagram depicting the method to directly adsorb and align a nano-wire on a solid surface without using any linker molecular layer in accordance with an embodiment of the present invention;

FIG. 5 shows various comparison photographs related to a carbon nano-tube adsorption property on various molecular layer;

FIG. 6 shows photographs of nano-wires adsorbed and aligned on a specific position of an Au surface utilizing a slippery molecular pattern;

FIG. 7 is various photographs representing carbon nano-tubes assembled on various solid surfaces in accordance with a method of the present invention;

FIG. 8 is a schematic diagram depicting a dip-pen nanolithography method among methods for patterning molecular layers;

FIG. 9 is a schematic diagram illustrating a micro-contact printing method among methods for patterning molecular layers;

FIG. 10 is a schematic diagram representing a photolithography method among methods for patterning molecular layers;

FIG. 11 is a schematic diagram presenting nano-structure based integrated circuit manufacturing capability using a method of the present invention;

FIG. 12 is a schematic diagram describing a process of assembling a multi nano-structure;

FIG. 13 is various photographs representing exemplary embodiments of each assembly process of the multi nano-structure shown in FIG. 12;

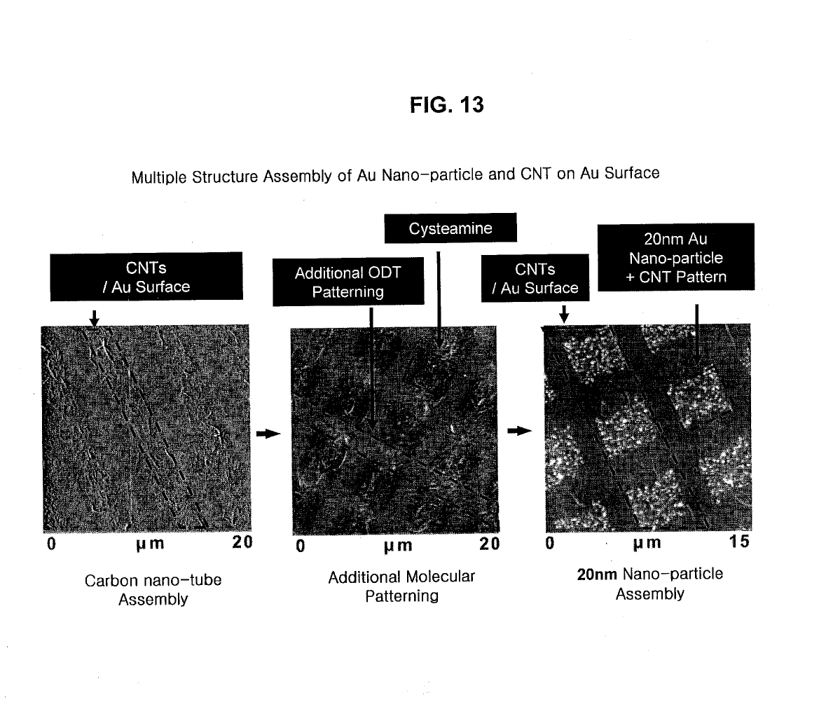

FIG. 14 is a schematic diagram showing a method for applying the signal amplification in accordance with the multi nano-structure of the present invention to a sensor; and

FIG. 15 is a fluorescent microscope image showing that a fibronectin protein is adsorbed only on the region where a carbon nano-tube is adsorbed and aligned.

### BEST MODE FOR THE INVENTION

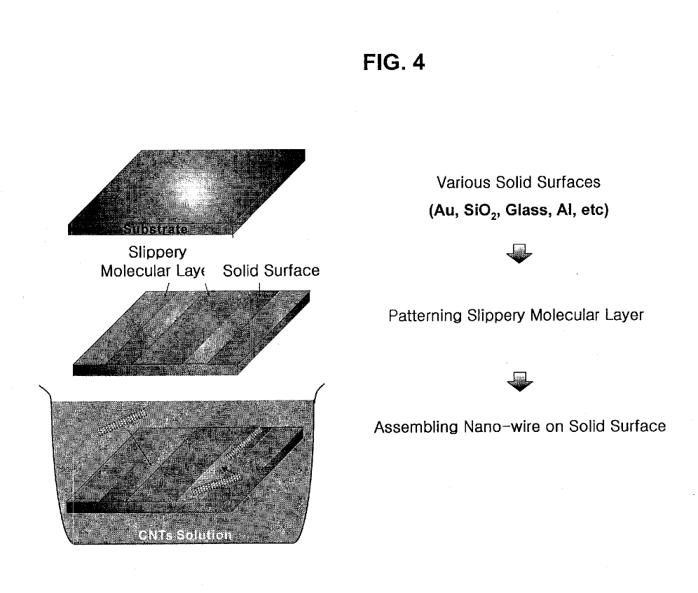

Hereinafter, the preferred embodiments of the present invention are described in detail with respect to FIG. 4. A nano-structure in the present invention means that it includes nano-particles, nano-tubes, nano-wire or the like and a combination thereof. And also, the nano-structure in the present invention means that it includes various shapes. For example, it includes Au nano-particles in a form of a sphere, FeOOH nano-particles in a form of an oval, Ag nano-particles in a form of a prism or the like.

The basic concept of the present invention is to utilize the interface energy difference between materials. Particularly, for the nano-structure to be adsorbed, if a molecular layer having higher interface energy than the bare solid surface is formed on the solid surface, the nano-structure can be more easily adsorbed on the bare solid surface.

Further, the nano-structure adsorbed on the molecular layer is also slid toward the bare solid surface to adapt to the most stable energy structure. In this concept, the present invention adopts the terminology such as the slippery molecular layer.

And, by using dip-pen nanolithography, micro-contact printing, photolithography, e-beam lithography, nano-grafting, nano-shaving, scanning tunneling microscope (STM) lithography or the like, the solid surface can be treated into slippery molecular patterns with a isotropic as well an anisotropic shape. Herein, the adsorption of nano-structure utilizes natural absorption forces or electric fields or the like included into all types of solid surfaces. In this result, the nano-structure can be directly adsorbed on the solid surface with various shape of patterns.

The difference between the present invention and prior art is as follows. The prior art employs a positive pattern transfer where the nano-structure is drawn to the desired position by covering the molecular layer drawing a predetermined nano-structure at the place where the nano-structure is designed to become adsorbed on the solid surface.

Meanwhile, the present invention employs a negative pattern transfer where the nano-structure is adsorbed directly on only the bare solid surface on which there is no the molecular layer by making the nano-structure slide on the molecular layer using interface energy difference, where the nano-structure has not to be adsorbed.

And, the characteristics of the present invention are that the nano-structure can directly adsorb on the solid surface. Generally, a linker molecule with a functional group can contaminate the nano-structure or the solid surface. However, for the present invention, since the nano-structure is adsorbed directly on the bare solid surface, the present invention can prevent the nano-structure or and the solid surface from being contaminated. Specifically, in case when a hydrophobic molecular layer not having nearly a chemical reactivity is used, the effect of the contamination prevention further increases.

On the other hand, in order to guide the sliding of the nano-structure adsorbed on a slippery molecular layer, the temperature of the nano-structure solution can be raised, or vibration can be applied to the solid surface.

And also, in the nano-structure solution, the amount of the nano-structure to be adsorbed can be controlled by applying a voltage to the slippery molecule patterned solid surface. That is, if a high voltage is applied to the solid surface, the amount of the nano-structure directly adsorbed on the solid surface increases by causing the nano-structure to slide on the solid surface.

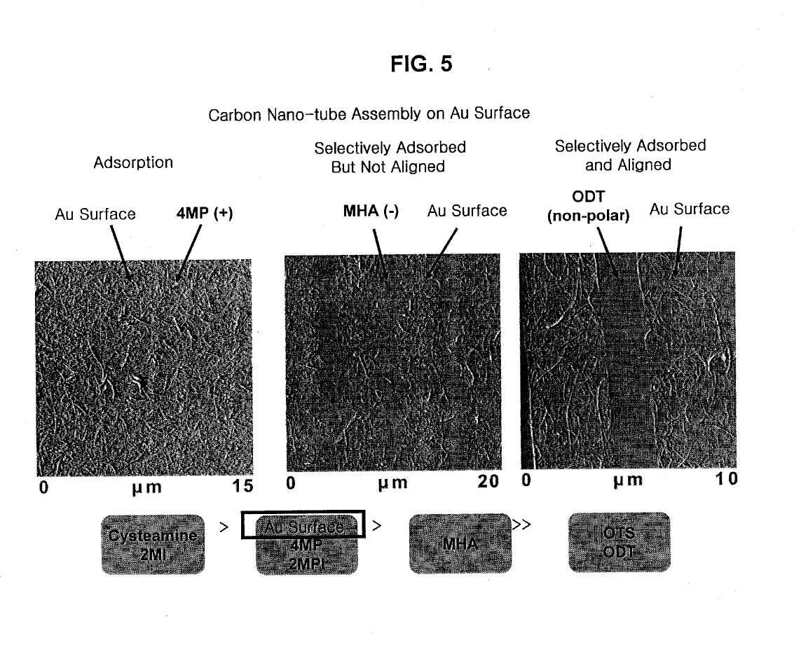

On the other hand, as shown in FIG. 5, in case when the nano-structure to be adsorbed is a carbon nano-tube, it is preferable that the slippery molecular layer is a hydrophobic molecular layer. And also, it is preferable that 1-octadecanethiol (hereinafter referring to as ODT) molecular is utilized to form the hydrophobic molecular layer on Au and Ag solid surfaces.

The present invention can assemble and align all types of nano-structure using the slippery molecular layer. More specifically, materials such as carbon, ZnO, Si, GaAs or the like can be used for the nano-structure.

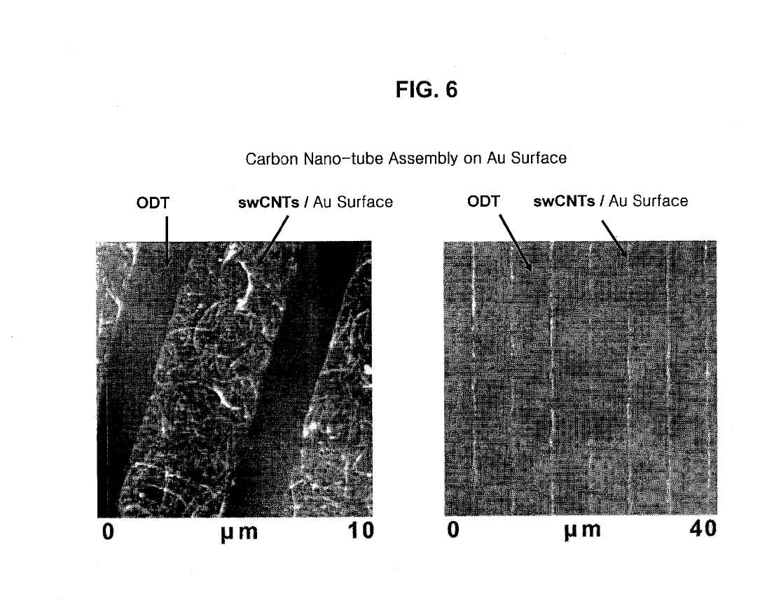

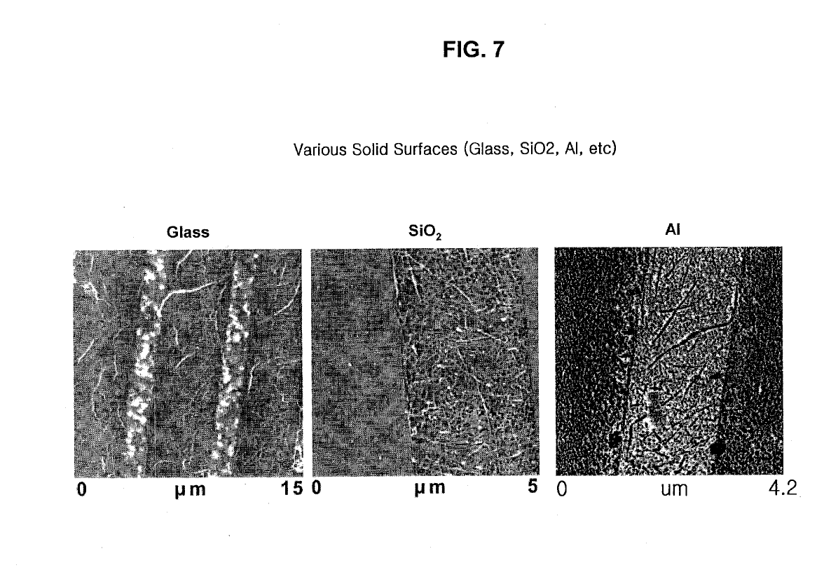

And also, the present invention can be applied to assembling and aligning nano-structures on most of solid surfaces. As shown in FIG. 6 and FIG. 7, for the carbon nano-tube, it is identified that the present invention can be applied to many types of solid surfaces such as Au, glass, SiO₂, Al or the like using the hydrophobic molecular layer. More particularly, FIG. 6 represents a structure of carbon nano-tubes adsorbed and aligned on a specific position of an Au surface by using a hydrophobic molecular layer; and FIG. 7 represents carbon nano-tubes assembled on various solid surfaces in accordance with a method of the present invention.

As an embodiment, solid surfaces and slippery molecular layers are listed on the following table 1. And also, the present invention can be also applied to a surface of mica and a surface of plastic.

TABLE 1

| Surface of solid | Molecular type | Specific example |
|---|---|---|
| Au | R—SH | C₁₂H₂₅SH, C₆H₅SH, n-hexadecanethiol, n- |
| | Ar—SH | octadecanethiol |
| | | n-docosanethiol, C₁₀H₂₁SH, C₈H₁₇SH, C₆H₁₃SH |
| | RSSR′(disulfides) | (C₂₂H₄₅)₂S₂ (C₁₉H₃₉)₂S₂, [CH₃(CH₂)₁₅S]₂ |
| | RSR′(sulfides) | [CH₃(CH₂)₉]₂S |
| | RSO₂H | C₆H₅—SO₂H |
| | R₃P | (C₆H₁₁)₃P |
| Ag | R—SH | C₁₂H₂₅SH, C₆H₅SH, n-hexadecanethiol, n- |
| | Ar—SH | octadecanethiol |
| | | n-docosanethiol, C₁₀H₂₁SH, C₈H₁₇SH, C₆H₁₃SH |
| Cu | R—SH | C₁₂H₂₅SH, C₆H₅SH, n-hexadecanethiol, n- |
| | Ar—SH | octadecanethiol |
| | | n-docosanethiol, C₁₀H₂₁SH, C₈H₁₇SH, C₆H₁₃SH |
| GaAs | R—SH | C₁₂H₂₅SH, C₆H₅SH, n-hexadecanethiol, n- |
| | Ar—SH | octadecanethiol |
| | | n-docosanethiol, C₁₀H₂₁SH, C₈H₁₇SH, C₆H₁₃SH |
| InP | R—SH | C₁₂H₂₅SH, C₆H₅SH, n-hexadecanethiol, n- |
| | Ar—SH | octadecanethiol |
| | | n-docosanethiol, C₁₀H₂₁SH, C₈H₁₇SH, C₆H₁₃SH |
| Pt | RNC | (C₅H₆)Fe(C₅H₅)—(CH₂)₁₂—NC |
| SiO₂, glass | RSiCl₃ | C₁₀H₂₁SiCl₃, C₁₂H₂₅SiCl₃, C₁₆H₃₃SiCl₃, |
| | RSi(OR′) | C₁₂H₂₅SiCl₃ |
| | | CH₂═CHCH₂SiCl₃, octadecyltrichlorosilane |
| Si | (RCOO)₂ (neat) | [CH₃(CH₂)₁₀COO]₂, [CH₃(CH₂)₁₆COO]₂ |
| Si—H | RCH═CH₂ | CH₃(CH₂)₁₅CH═CH₂, CH₃(CH₂)₈CH═CH₂ |
| | RLi, RMgX | C₄H₉Li, C₁₈H₃₇Li, C₄H₉MgX, C₁₂H₂₅MgX, X—Br or |
| | | Cl |
| Metal oxides | RSiCl₃ | C₁₀H₂₁SiCl₃, C₁₂H₂₅SiCl₃, C₁₆H₃₃SiCl₃, |
| | RSi(OR′)₃ | C₁₂H₂₅SiCl₃ |
| | | CH₂═CHCH₂SiCl₃, octadecyltrichlorosilane |
| | RCOO-•••Mon | C₁₅H₃₁COOH, H₂C═CH(CH₂)₁₉COOH |
| | RCONHOH | |
| ZrO₂ | RPO₃H₂ | |
| In₂O₃/SnO₂ (ITO) | RPO₃H₂ | |
| Various Oxide | RSiCl₃ | C₁₀H₂₁SiCl₃, C₁₂H₂₅SiCl₃, C₁₆H₃₃SiCl₃, |
| surface | RSi(OR′)₃ | C₁₂H₂₅SiCl₃ |
| | | CH₂═CHCH₂SiCl₃, octadecyltrichlorosilane |

The nano-structure solution means a solution that contains a predetermined nano-structure. The predetermined nano-structure is immerged into a solvent capable of easily dispersing the predetermined nano-structures and the nano-structures can be dispersed into the solvent for several minutes to several days using an ultrasonic cleaning device.

In case when the nano-structure is V₂O₅, it is preferable that deionized water is employed as a solvent of the nano-structure solution, and in case when the nano-structure is ZnO, it is preferable that ethanol or deionized water is employed as a solvent of the nano-structure solution.

If the carbon nano-tube is prepared, 1,2-dichlorobenzene, 1,3,4-trichlorobenzene, 1,3-dichlorobenzene, dichloroethane, chlorobenzene or the like can be employed as a solvent.

In this case, it is preferable that the concentration of the nano-structure has the range from 0.001 to 10 mg/ml. For example, in a multi nano-structure, in order to reserve a space to adsorb the nano-particle, the concentration of the nano-structure has to be as low as approximately 0.001 mg/ml when the carbon nano-tube is to be less adsorbed on the solid surface or when the carbon nano-tube is to be adsorbed on the solid surface in a shape of thin line as shown in FIG. 6.

On the other hand, in case when the carbon nano-tube is adsorbed on the solid surface as much as possible, it is preferable that the concentration is as high as approximately 10 mg/ml. Since the adsorption does not occur further although the concentration becomes larger than 10 mg/ml, it is preferable that the concentration of the nano-structure has the range from 0.001 to 10 mg/ml.

And, it is preferable that the dispersion time is ranging from one minute to 3 days in the ultrasonic cleaning device, since it is preferable that the dispersion time becomes approximately one minute in case when a large amount of nano-structure bundles are adsorbed on the solid surface and the dispersion time becomes over several days in case when the nano-structure is adsorbed one by one.

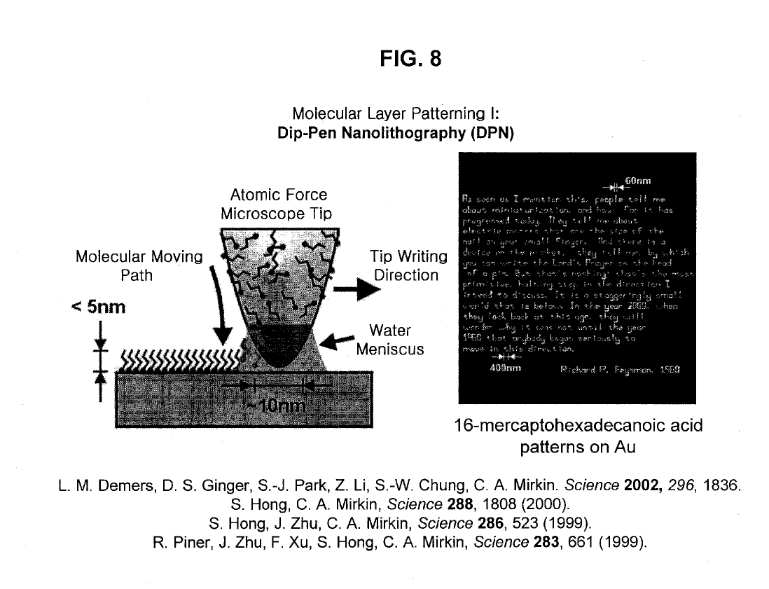

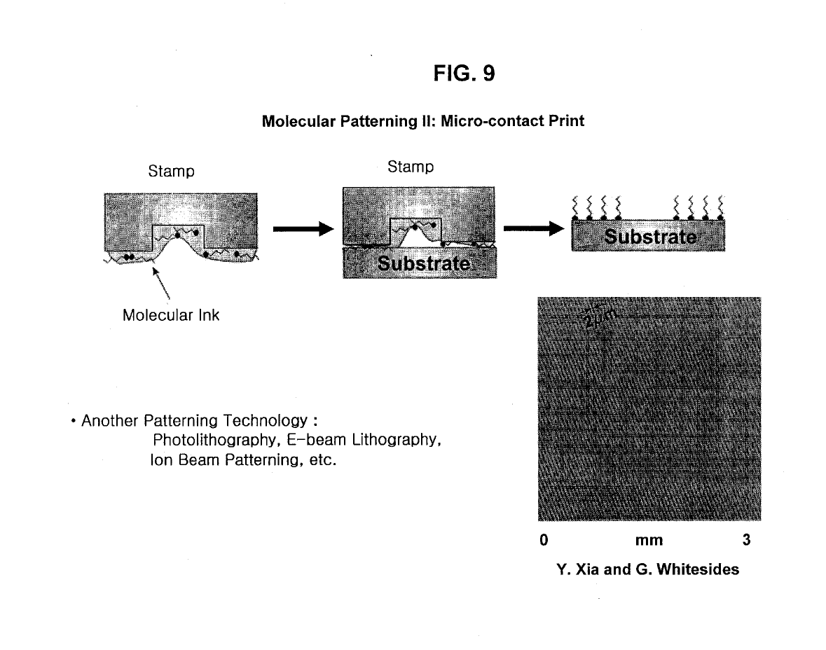

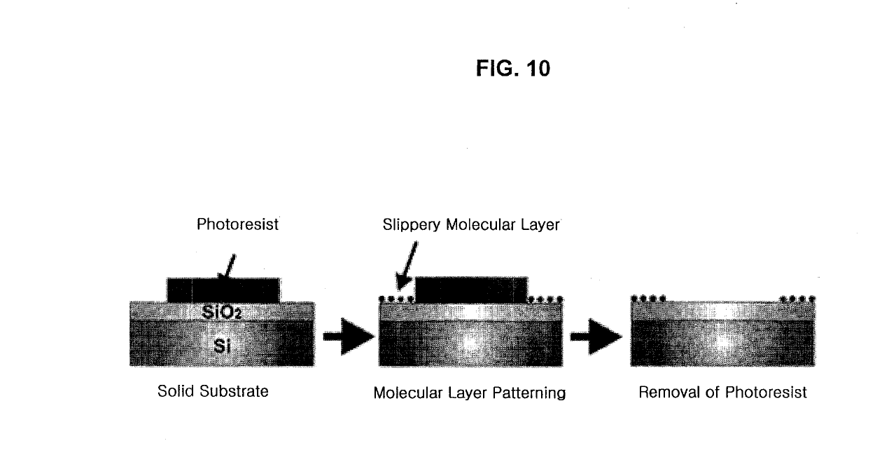

In the present invention, the slippery molecular layer can be patterned by using dip-pen nanolithography (referring to FIG. 8), micro-contact printing (referring to FIG. 9), photolithography (referring to FIG. 10), e-beam lithography, nano-grafting, nano-shaving, scanning tunneling microscope (STM) lithography or the like and all of the other allowable patterning methods can be utilized.

Meanwhile, when compatibility with a conventional semiconductor process is considered, particularly it is preferable that the patterning is performed by the photolithography method.

Hereinafter, embodiments of the present invention are described in detail.

### FIRST EMBODIMENT

Patterning a Molecular Layer Using a Photolithography Method

First, a photoresist pattern is formed by a photolithography method. Thereafter, when the photoresist patterned solid sample is immerged into slippery molecular solution, the slippery molecular layer can be patterned by adsorbing the molecular on a site where the photoresist is not covering. At this time, the slippery molecules have to dissolve in a solvent that does not to remove the photoresist.

In case when the octadecyltrichlorosilane is used as one of the slippery molecular layers in patterning the carbon nano-tube or V₂O₅ nano-wire on oxide surfaces such as SiO₂, glass, most metal surface or the like, anhydrous hexane is used as a solvent.

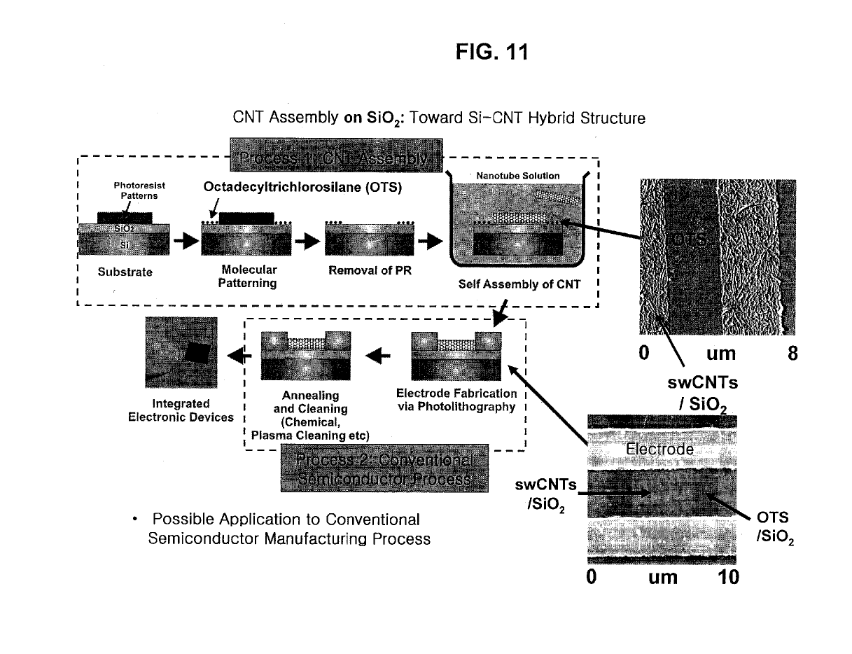

In this case, after moistures of the surface are removed by washing the solid sample with the clean anhydrous hexane solution, the solid sample is immerged into the solution containing the slippery molecules. In the next step, the slippery molecular layer can be obtained by dissolving and removing the photoresist (for example, the removal can be performed by acetone for the AZ series photoresist) (referring to FIG. 10 and FIG. 11).

### SECOND EMBODIMENT

Patterning a Molecular Layer Using a Micro-Contact Printing Method

The ODT molecular layer is patterned by the micro-contact printing method under a condition that the stripe 2 μm/4 μm stamp coated with the 3 mM ODT solution is in contact with the Au/Ti layer deposited on Si wafer for 8 seconds. Thereafter, the solid sample is immerged into the carbon nano-tube solution of a 3 mg/ml carbon nano-tube concentration for 10 seconds. The result as shown in the left photograph of FIG. 6 can be obtained.

Meanwhile, the ODT molecular layer is patterned by the micro-contact printing method under a condition that the stripe 4 μm/2 μM stamp coated with 3 mM ODT solution is in contact with the Au/Ti layer deposited on Si wafer by a for 20 seconds. Thereafter, the solid sample is immerged into the carbon nano-tube solution of 0.01 mg/ml carbon nano-tube concentration. The result shown in the right photograph of FIG. 6 can be obtained.

### FIRST MANUFACTURING EXAMPLE

### Manufacturing an Integrated Circuit Using a Carbon Nano-Tube

Generally, conventional semiconductor patterning technology utilizes a photolithography method. Therefore, after the slippery molecular layer is patterned on a desired solid sample using a photolithography method, this patterned sample is immerged into the carbon nano-tube solution. And then, carbon nano-tubes are adsorbed and aligned on desired positions where the slippery molecular layer is not patterned. In this case, the mass production of the nano-tube integrated circuit can be possible with utilizing the conventional semiconductor processes as they are.

In order to manufacture further complex integrated circuits, the integrated circuit including the carbon nano-tubes can be manufactured by performing the conventional semiconductor processes before and after the carbon nano-tube assembly.

Examples of the possible semiconductor processes before and after the carbon nano-tube process are etching, deposition, photolithography method, oxide deposition or the like.

Using the above-described semiconductor processes, the integrated circuit element such as an interconnectors, a transistor channels, vias, resistors, an oscillators or the like can be manufactured by using the carbon nano-tubes.

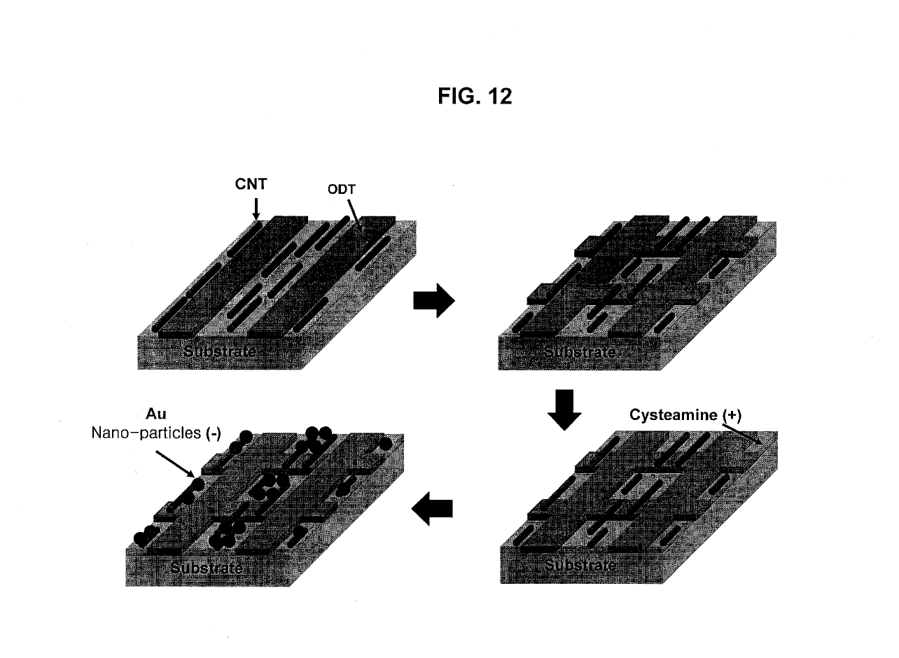

On the other hand, the nano-structure and the nano-particle can be adsorbed on the solid surface in multiple. The embodiment is described in detail hereinafter. As shown in FIG. 12, the slippery molecular layer made of the ODT is patterned on the solid surface, and the carbon nano-tube is adsorbed on the solid surface where the slippery molecular layer is not patterned. Thereafter, the ODT layer or the different molecular layer is additionally patterned, and cysteamine containing a positive charge is adsorbed on a portion which is not patterned with the ODT molecular layer. And then, it is immerged into the solution containing Au nano-particles, the Au nano-particle containing a negative charge is adsorbed on the cysteamine having the low interface energy.

The multi nano-structure of the present invention can be utilized as a sensor to amplify a signal. The signal is amplified by sending the signal to the solid surface where nano-structures are selectively positioned or aligned in accordance with the present invention. Therefore, the sensor improving a performance in sensing the signal can be obtained.

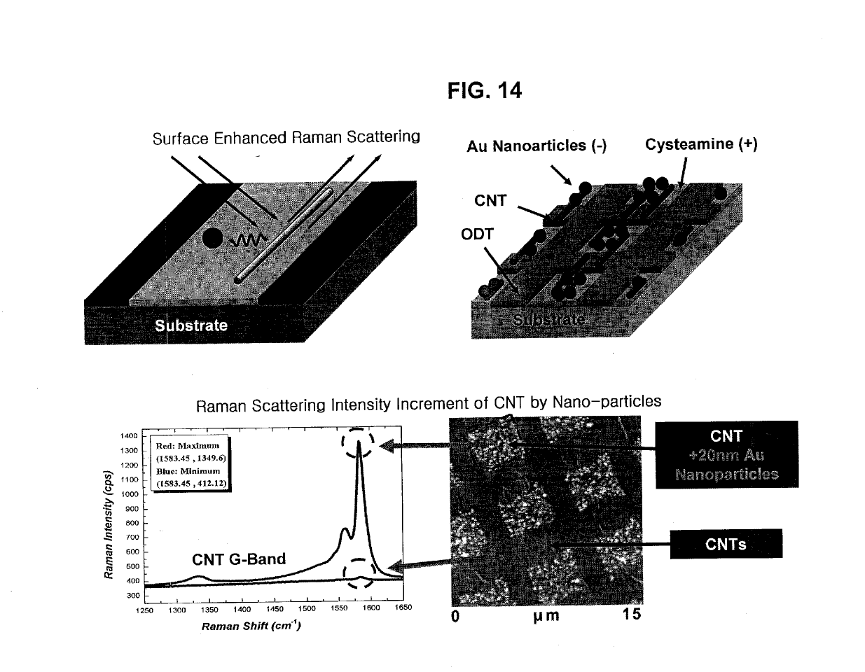

In case when the nano-structure and the additional nano-structure are adsorbed to the solid sample in multiple, the signal is further amplified. As one embodiment, as shown in FIG. 14, in case when the carbon nano-tube and the Au nano-particle are adsorbed on the Au solid surface, it can be identified that much higher Raman intensity is obtained in comparison with the case when only the carbon nano-tube is adsorbed.

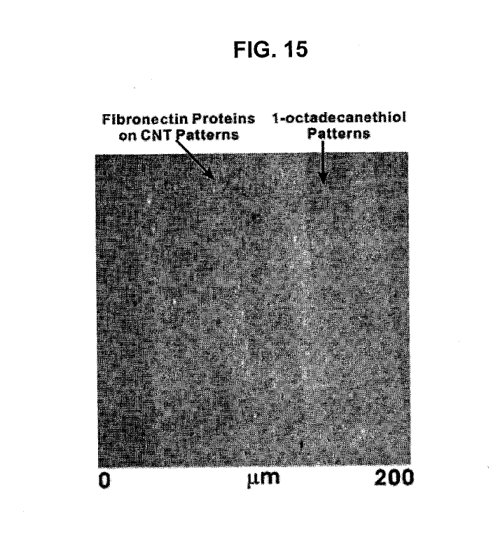

Meanwhile, the present invention can be applied to adsorbing, aligning and cultivating bio-structures such as deoxyribonucleic acids (DNAs), ribonucleic acids (RNAs), proteins, antigens, antibodies, cells or the like. More specifically, a protein such as fibronectin can be adsorbed on the carbon nano-tube formed on the solid surface. This may be useful in manufacturing a device such as a protein chip. FIG. 15 is a fluorescent microscope image photograph showing that fibronectin proteins are adsorbed only on regions where carbon nano-tubes are adsorbed and aligned, wherein bright portions represent the regions where the fibronectin proteins are adsorbed.

On the other hand, in case when cells are adsorbed, the adsorbed bio-cell can be cultivated on the solid surface into the shape of the nano-structure such as the carbon nano-tube formed on the solid surface with various patterns. This is very useful in cultivating the bio-cell into a desired shape of internal organs.

While the present invention has been described with respect to certain preferred embodiments, it will be apparent to those skilled in the art that various changes and modifications may be made without departing from the scope of the invention as defined in the following claims.

1. A method for selectively positioning or aligning a nano-structure on solid surfaces using a slippery molecular layer as a method patterning the nano-structure on the solid surface, the method comprising the steps of:
patterning the slippery molecular layer on the solid surface into an isotropic or an anisotropic shape, wherein an interface energy for the nano-structure to be adsorbed on the slippery molecular layer is higher than that on the bare solid surface;
immerging the solid, of which the surface is patterned by the slippery molecular layer, into a nano-structure solution containing the nano-structure;
directly adsorbing the nano-structure on the bare solid surface, which is not surface treated region by the slippery molecular layer, with adsorbing and sliding the nano-structure on the slippery molecular layer; and
removing the nano-structure adsorbed on the slippery molecular layer by cleaning the solid with a washing solution.

2. The method as recited in claim 1, further comprising the steps of:
further patterning the same of the previously patterned slippery molecular layer or a different slippery molecular layer on the solid surface at which the nanostructure is selectively positioned and aligned;
further patterning a nano-structure adsorption molecular layer with a lower interface energy for the additional nano-structure to be further adsorbed on a region out of the slippery molecular layer; and
adsorbing the additional nano-structure on the nano-structure adsorbing molecular layer by immerging the solid into the solution containing the additional nano-structure.

3. The method as recited in claim 1, wherein the step of patterning the slippery molecular layer on the solid surface is selected from a group of techniques consisting of dip-pen nanolithography, micro-contact printing, photolithography, e-beam lithography, nano-grafting, nano-shaving, scanning tunneling microscope (STM) lithography or the like.

4. The method as recited in claim 3, for the photolithography method, further includes the steps of:
removing the photoresist formed to pattern the slippery molecular layer after the slippery molecular layer is patterned.

5. The method as recited in claim 3, wherein, for the micro-contact printing method, after an octadecanethiol molecular layer is patterned on the solid surface by the micro-contact printing method under a condition that the stripe 2 μm/4 μm s tamp coated with 3 mM octadecanethiol solution is in contact with the Au/Ti layer deposited on Si wafer for 8 seconds, immerging a solid surface sample into a carbon nano-tube solution of 3 mg/ml carbon nano-tube concentration during 10 seconds.

6. The method as recited in claim 3, wherein, for the micro-contact printing method, after an octadecanethiol molecular layer is patterned on the solid surface by the micro-contact printing method under a condition that the stripe 2 μm/4 μm stamp coated with 3 mM octadecanethiol solution is in contact with the Au/Ti layer deposited on Si wafer for 20 seconds, immerging the solid surface sample into a carbon nano-tube solution of 0.01 mg/ml carbon nanotube concentration during 5 seconds.

7. The method as recited in claim 1, wherein, in case when the nano-structure is a carbon nano-tube, the slippery molecular layer is a hydrophobic molecular layer.

8. The method as recited in claim 1, wherein the nano-structure adsorption molecular layer is cysteamine and the additional nano-structure is an Au nano-particle.

9. The method as recited in claim 1, wherein a voltage is applied to the solid surface patterned into the slippery molecular layer.

10. The method as recited in claim 9, wherein the voltage is applied while the solid is immerged into the nano-structure solution.

11. The method as recited in claim 1, wherein the temperature of the nano-structure solution or the additional nano-structure solution is raised, or a vibration is applied to the nano-structure solution or the additional nano-structure solution.

12. The method as recited in claim 1, wherein, in case when the nano-structure is V₂O₅, the nano-structure solution employs deionized water as a solvent.

13. The method as recited in claim 1, wherein, in case when the nano-structure is ZnO, the nano-structure solution employs ethanol or deionized water as a solvent.

14. The method as recited in claim 1, wherein, in case when the nano-structure is a carbon nano-tube, the nano-structure solvent employs one selected from a group consisting of 1,2-dichlorobenzene, 1,3,4-trichlorobenzene, 1,3-dichlorobenzene, dichloroethane, chlorobenzene or the like as a solvent.

15. The method as recited in claim 14, the carbon nano-tube solution of the carbon nano-tube is manufactured by dispersing a solvent containing the carbon nanostructure in the concentration ranging from 0.001 to 10 mg/ml in an ultrasonic cleaning device for approximately 1 minute to 3 days.

16. The method as recited in claim 1, wherein the washing solution is the solvent of nano-structure solution or the solvent not to deviate the nano-structure adsorbed on the solid surface.

17. The method as recited in claim 1, wherein if a signal is transmitted to the solid surface at which the nano-structure is selectively positioned or aligned, the transmitted signal is amplified and the amplified signal is detected.

18. A method for manufacturing a bio-structure aligned or cultivated on a nano-structure selectively aligned using a slippery molecular layer, the method comprising the steps of:
aligning the nano-structure into a predetermined shape on a solid surface; and
aligning and cultivating the bio-structure by adsorbing the bio-structure on the nano-structure with the predetermined shape,
wherein the step of aligning the nano-structure into a predetermined shape includes the steps of:
patterning the slippery molecular layer on the solid surface into an isotropic or an anisotropic shape, wherein the interface energy for the nano-structure to be adsorbed is higher than that of the bare solid surface;
immerging the solid, of which the surface is patterned by the slippery molecular layer, into a nano-structure solution containing the nano-structure;
directly adsorbing the nano-structure on the solid surface which is not surface treated by the slippery molecular layer with adsorbing and sliding the nanostructure on the slippery molecular layer; and
removing the nano-structure adsorbed on the slippery molecular layer by cleaning the solid with a washing solution.

19. The method as recited in claim 18, wherein the bio-structure is one selected from a group consisting of deoxyribonucleic acids (DNAs), ribonucleic acids (RNAs), proteins, antigens, antibodies or the like.
